(19) United States
(12) Patent Application Publication
(10) Pub. No.: US 2008/0054794 A1
(43) Pub. Date: Mar. 6, 2008

(54) Organic Electroluminescence Device, Image Display Apparatus and Lighting Apparatus Including the Same, Charge Transport Material and Charge Transport Layer Forming Ink Including the Same

(75) Inventors: Yumiko Hatanaka, Nara (JP); Michiya Fujiki, Nara (JP); Akira Nishimoto, Nara (JP)

Correspondence Address: SHARP KABUSHIKI KAISHA;C/O KEATING & BENNETT, LLP, 8180 GREENSBORO DRIVE, SUITE 850, MCLEAN, VA, 22102, US

(73) Assignees: Michiya FUJIKI, Ikoma-shi, Nara (JP); SHARP KABUSHIKI KAISHA, Osaka-shi, Osaka (JP)

(21) Appl. No.: 11/570,665

(22) PCT Filed: Jun. 22, 2005
(86) PCT No.: PCT/JP05/11892

§ 371 Date: Apr. 6, 2007

(30) Foreign Application Priority Data
Jun. 23, 2004 (JP) 2004-184509

(51) Int. Cl. H01L 51/54; C09K 11/06; H01L 51/30

(52) U.S. Cl. 313/504; 524/612; 528/423

(57) ABSTRACT

An organic EL device includes a substrate, a first electrode, a luminous layer, a second electrode and a charge transport layer. The charge transport layer is provided between the luminous layer and the first electrode or between the luminous layer and the second electrode. The charge transport layer is made of a charge transport material including a polymeric compound having, in a polymer main chain, a condensed ring structure composed of a plurality of rings including a pyrrole ring with the main chain being a conjugated system.

### BACKGROUND OF THE INVENTION

1. Field of the Invention

The present invention relates to an organic electroluminescence device, an image display apparatus and a lighting apparatus including the organic electroluminescence device, a charge transport material and a charge transport layer forming ink including the charge transport material.

2. Description of the Related Art

An electroluminescence device (hereinafter sometimes referred to as an “EL device”) is a selfluminous all-solid device. An EL device has high visibility and is good at impact durability. Therefore, it is expected to apply in a wide range of fields.

EL devices are roughly divided into inorganic EL devices using inorganic luminescent materials and organic EL devices using organic luminescent materials.

Currently, inorganic EL devices are widely used. An inorganic EL device needs, however, a high AC voltage of 200 V or more for driving. Also, the inorganic EL device is expensive in the fabrication cost and has low brightness. On the other hand, the driving voltage of an organic EL device is lower than that of an inorganic EL device and the fabrication is easier. Therefore, organic EL devices are recently being earnestly studied.

The study of an organic EL device was started from a device using, as a luminous layer, a single-crystal thin film of anthracene. However, it was difficult to form a thin film of single-crystal anthracene. At the early stage of the study, the thickness of the luminous layer was as large as approximately 1 mm. Therefore, the driving voltage was as high as 100 V or more.

Therefore, attempts to obtain a single-crystal thin film of anthracene through vapor deposition are being made. However, even in an organic EL device using an anthracene thin film formed through the vapor deposition as a luminous layer, the driving voltage is as high as 30 V or more. Also, in an organic EL device using an anthracene thin film, the density of carriers such as electrons and holes in the luminous layer is low. Therefore, the probability of excitation caused by recombination of the carriers is low, which leads to a problem that sufficient brightness cannot be attained.

Recently, as an organic EL device with a low driving voltage and high brightness, a separated-function type organic EL device including a hole transport layer made of an organic compound having a hole transporting function and a luminous layer made of an organic luminescent material having an electron transporting function has been proposed. In general, the hole transport layer and the luminous layer are formed through vacuum evaporation. The separated-function type organic EL device has a low driving voltage of approximately 10 V. Also, it has high brightness of 1000 cd/m² or more. Therefore, this type of device is recently being earnestly studied.

In a separated-function type organic EL device, in order to attain sufficient luminous performance, it is necessary to form each organic layer in a very small thickness of, for example, 0.1 μm or less. However, as the thickness of an organic layer is smaller, more pin holes are formed in the organic layer. Accordingly, a separated-function type organic EL device has a problem that it is difficult to simultaneously attain high luminous performance, high productivity and a large area.

Also, it is necessary to drive a separated-function type organic EL device with a high current density of several mA/cm² or more. Therefore, a large amount of heat is generated through the driving. Accordingly, a hole transport material such as a tetraphenyl diamine derivative is gradually crystallized. This lowers the hole transporting function of the hole transport layer, and hence, the brightness of the organic EL device is lowered with time. As a result, the separated-function type organic EL device has a problem that it is poor in stability and has a short life as a product.

In consideration of this problem, a separated-function type organic EL device using, as a hole transport material, starburstamine that can attain a stable amorphous state is proposed. Also, a separated-function type organic EL device using, as a hole transport material, a polymer of polyphosphazene having triphenyl amine in a side chain is proposed.

On the other hand, an organic EL device having a polymer single-layered structure including a luminous layer alone as the organic layer is recently being earnestly studied and developed. In an organic EL device having a polymer single-layered structure, a conductive polymer such as polyphenylene vinylene, hole transporting polyvinyl carbazole (hereinafter sometimes referred to as “PVCz”) including both an electron transport material and a luminous pigment, or the like is used as a polymer for forming a luminous layer. The organic EL device having a polymer single-layered structure has higher productivity than the aforementioned separated-function type organic EL device. However, the organic EL device having a polymer single-layered structure has a problem that the driving voltage is high and the luminous efficiency and the stability are low.

In consideration of such a problem, a stacked two-layered organic EL device is proposed. A stacked two-layered organic EL device includes a luminous layer and an organic layer stacked on the luminous layer and including 3,4-polyethylenedioxythiophene/polystyrene sulfonate (hereinafter sometimes referred to as “PEDOT/PSS”). A stacked two-layered organic EL device has, as compared with an organic EL device having a polymer single-layered structure, a low driving voltage, high luminous efficiency and high stability. However, as compared with a separated-function type organic EL device, the driving voltage is high and the luminous efficiency is low. Furthermore, its life time as a device is disadvantageously short. A stacked two-layered EL device has a short life because charges cannot be effectively confined in its luminous layer.

In consideration of these problems of a stacked two-layered EL device, a stacked three-layered EL device in which a PVCz layer is additionally stacked between a luminous layer and a hole injection electrode of a stacked two-layered EL device is proposed. A stacked three-layered EL device can attain a lower driving voltage and higher luminous efficiency than a stacked two-layered EL device.

Furthermore, an organic EL device including a PVCz layer as an electron blocking layer for suppressing outflow of electrons from a luminous layer is proposed (for example, see J. Appl. Phys., Vol. 89, 4, 2343-2350 (2001)). Since PVCz has a wide band gap, the PVCz layer exhibits a high electron blocking function. Accordingly, this organic EL device is described to have high quantum efficiency.

However, a separated-function type organic EL device using, as a hole transport material, starburstamine or a polymer having triphenyl amine in a side chain of polyphosphazene has a problem that the property for injecting holes from an anode and the property for transporting holes to a luminous layer are so low that sufficiently high luminous efficiency cannot be attained.

A separated-function type organic EL device using, as a hole transport material, a polymer of polyphosphazene having triphenyl amine in a side chain has a problem that a high current density cannot be attained and hence sufficient brightness cannot be obtained.

Furthermore, since a stacked three-layered EL device or an organic EL device including a PVCz layer as an electron blocking layer includes a PVCz layer with low conductivity, it has a problem that the driving voltage is high and the luminous efficiency is low.

### SUMMARY OF THE INVENTION

The present invention was devised in consideration of these conventional problems, and an object of the invention is providing an organic EL device with a low driving voltage, high luminous efficiency and a long life.

The organic electroluminescence device of this invention includes a substrate, a first electrode, a luminous layer, a second electrode and a charge transport layer. The first electrode is provided on the substrate. The luminous layer is provided on the first electrode. The second electrode is provided on the luminous layer. In other words, the luminous layer is provided between the first electrode and the second electrode. The charge transport layer is provided between the luminous layer and the first electrode or between the luminous layer and the second electrode. The charge transport layer is made of a charge transport material. The charge transport material includes a polymeric compound. The polymeric compound has, in a polymer main chain, a condensed ring structure composed of a plurality of rings including a pyrrole ring. The polymer main chain of the polymeric compound is a conjugated system.

In the organic electroluminescence device of this invention, the polymeric compound may have, in the polymer main chain, carbazole or carbazole derivative represented by the following Chemical Formula 1 with the polymer main chain being the conjugated system: 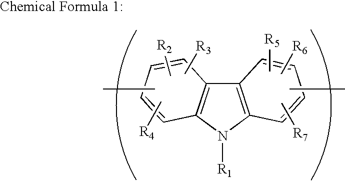
wherein each of R₁ through R₇ is a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

The carbazole or carbazole derivative represented by Chemical Formula 1 is preferably polymerically bonded at the 3,6 position or 2,7 position.

In the organic electroluminescence device of this invention, the charge transport layer is preferably a hole transport layer provided between the luminous layer and the first electrode.

The hole transport layer preferably controls movement of electrons from the luminous layer to the hole transport layer.

Also, an absolute value of electron affinity of the hole transport layer is preferably smaller than an absolute value of electron affinity of the luminous layer.

The organic electroluminescence device of this invention may further include a hole injection layer between the luminous layer and the first electrode.

The charge transport material of this invention includes a polymeric compound having, in a polymer main chain, a condensed ring structure composed of a plurality of rings including a pyrrole ring with the polymer main chain being a conjugated system.

In the charge transport material of this invention, the polymeric compound may have, in the polymer main chain, carbazole or carbazole derivative represented by the aforementioned Chemical Formula 1 with the polymer main chain being the conjugated system.

The charge transport layer forming ink of this invention includes an organic solvent having a boiling point of 110° C. or more; and a charge transport material dissolved in the organic solvent and including a polymeric compound. The polymeric compound has, in a polymer main chain, carbazole or carbazole derivative represented by Chemical Formula 2 below. The polymer main chain of the polymeric compound is a conjugated system. 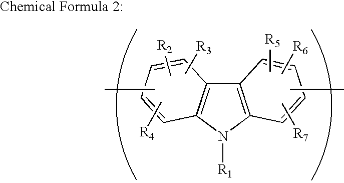
wherein R₁ is an alkyl group with a carbon number of 2 or more or an arylalkyl group with a carbon number of 6 or more, and each of R₂ through R₇ is a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

In the charge transport layer forming ink of this invention, the solvent may be an aromatic organic solvent such as toluene, xylene, trimethylbenzenes, tetralins, tetramethylbenzens and tetraethylbenzenes.

The organic electroluminescence image display apparatus (hereinafter sometimes referred to as the “organic EL image display apparatus”) of this invention includes the organic EL device according to the invention.

The organic electroluminescence lighting apparatus (hereinafter sometimes referred to as the “organic EL lighting apparatus”) of this invention includes the organic EL device according to the invention.

### BRIEF DESCRIPTION OF THE DRAWINGS

FIG. 1 is a cross-sectional view of an organic EL device according to Embodiment 1.

FIG. 2 is a cross-sectional view of an organic EL image display apparatus according to Embodiment 2.

FIG. 3 is a cross-sectional view of an organic EL device of an example.

FIG. 4 is an explanatory diagram for schematically showing the energy level of the organic EL device of the example.

FIG. 5 is an explanatory diagram for schematically showing the energy level of an organic EL device of a comparative example.

### DETAILED DESCRIPTION OF PREFERRED EMBODIMENTS

Preferred embodiments of the invention will now be described in detail with reference to the accompanying drawings.

### Embodiment 1

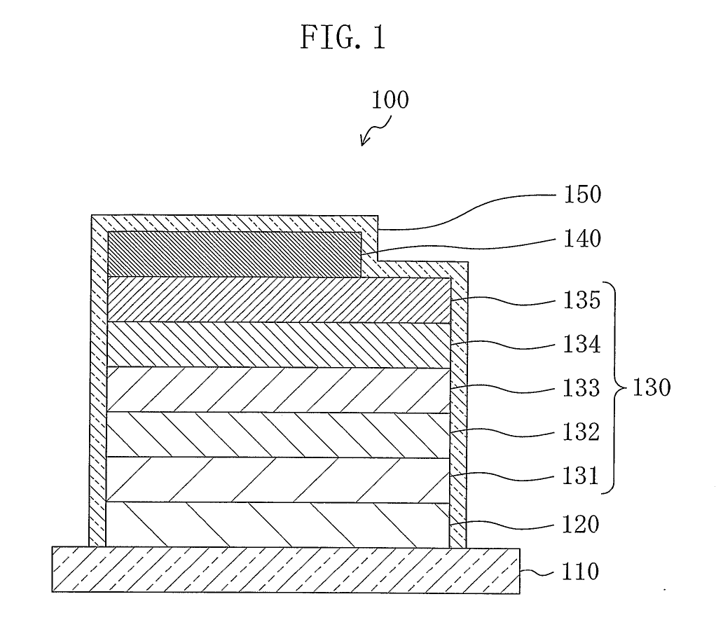

FIG. 1 is a cross-sectional view of an organic EL Device 100 of Embodiment 1.

The organic EL device 100 includes a substrate 110, a first electrode 120, an organic layer 130 including a luminous layer 133, and a second electrode 140. The first electrode 120 is provided on the substrate 110. The organic layer 130 is provided on the first electrode 120. The second electrode 140 is provided on the organic layer 130. The organic electroluminescence device 100 is provided with a sealing cap 150 for covering the first electrode 120, the organic layer 130 and the second electrode 140.

The organic layer 130 includes a hole injection layer 131, a hole transport layer 132, the luminous layer 133, an electron transport layer 134 and an electron injection layer 135. The hole injection layer 131 is provided on the first electrode 120. The hole transport layer 132 is provided on the hole injection layer 131. The luminous layer 133 is provided on the hole transport layer 132. The electron transport layer 134 is provided on the luminous layer 133. The electron injection layer 135 is provided on the electron transport layer 134.

The organic EL device 100 includes, as a charge transport layer, the hole injection layer 131, the hole transport layer 132, the electron transport layer 134 and the electron injection layer 135. In other words, the organic layer 130 is composed of the luminous layer 133, the hole injection layer 131, the hole transport layer 132, the electron transport layer 134 and the electron injection layer 135. However, the invention is not limited to this structure. For example, the organic layer 130 may be composed of the luminous layer and at least one of the hole injection layer 131, the hole transport layer 132, the electron transport layer 134 and the electron injection layer 135.

The first electrode 120 injects holes into the organic layer 130. The second electrode 140 injects electrons into the organic layer 130. The hole injection layer 131 improves the efficiency for injecting holes into the luminous layer 133. The hole transport layer 132 improves the efficiency for transporting the holes injected from the first electrode 120 to the luminous layer 133. The electron injection layer 135 improves the efficiency for injecting electrons from the second electrode 140 to the luminous layer 133. The electron transport layer 134 improves the efficiency for transporting the electrons injected from the second electrode 140 to the luminous layer 133.

In the organic EL device 100, the holes injected from the first electrode 120 through the hole injection layer 131 and the hole transport layer 132 and the electrons injected from the second electrode 140 through the electron injection layer 135 and the electron transport layer 134 are recombined in the luminous layer 133. Energy obtained through this recombination excites organic luminous molecules included in the luminous layer 133. Light is emitted when the excited organic luminous molecules are deactivated.

The substrate 110 can be made of an inorganic material, a plastic material, an insulating material or the like. Examples of the inorganic material are glass and quartz. An example of the plastic material is polyethylene terephthalate. An example of the insulating material is ceramic such as alumina.

Also, the substrate 110 may be a metal substrate coated with an insulating material. Examples of the metal substrate are an aluminum substrate and a stainless steel (SUS) substrate. Examples of the insulating material are SiO₂ and an organic insulating material. Alternatively, the substrate 110 may be a metal substrate having the surface thereof subjected to insulating processing. An example of the method for the insulating processing is anode oxidation.

The substrate 110 may have a switching device such as a thin film transistor (TFT) device. In this case, the substrate 110 preferably has such heat resistance that it is not distorted at a temperature of, for example, 500° C. or more. In particular, when the TFT device is formed through high temperature process, the substrate 110 preferably has heat resistance against 1000° C. or more.

In order to realize high efficiency for injecting holes into the organic layer 130, the first electrode 120 is preferably made of a material having a large absolute value of the work function. Thus, high luminous efficiency can be realized. Therefore, the organic EL device 100 can attain high brightness. Examples of the material having a large absolute value of the work function are gold (Au), platinum (Pt) and nickel (Ni).

In the case where the organic EL device 100 employs a bottom emission method in which the light emission of the luminous layer 133 is taken out from the side of the first electrode 120, the first electrode 120 is preferably made of a material with high luminous transmittance. Thus, the efficiency for taking out the light emission of the luminous layer 133 can be improved. Examples of the material with high luminous transmittance are indium tin oxide (ITO), indium zinc oxide (IZO), fluorine-doped tin oxide (FTO) and tin oxide (SnO₂).

Alternatively, in the case where the organic EL device 100 employs a top emission method in which the light emission of the luminous layer 133 is taken out from the side of the second electrode 140, the first electrode 120 is preferably made of a light reflecting material. In this case, light emitted from the luminous layer 133 to the side of the first electrode 120 is reflected on the first electrode 120 with the light reflecting property toward the second electrode 140. Therefore, the efficiency for taking out the light emission of the luminous layer 133 can be improved. Examples of the light reflecting material are aluminum (Al) and platinum (Pt).

In the case where the organic EL device 100 employs the top emission method, the first electrode 120 may have a layered structure including a layer made of a material having a large work function and a layer made of a material with high light reflectance. When such a layered structure is employed, high efficiency for injecting holes into the organic layer 130 and high efficiency for taking out the light emission of the luminous layer 133 can be both realized.

In order to realize high efficiency for injecting electrons into the organic layer 130, the second electrode 140 is preferably made of a material with a small absolute value of the work function. Examples of the material with a small absolute value of the work function are calcium (Ca), cerium (Ce), cesium (Cs), barium (Ba) and magnesium (Mg).

In the case where the organic El device 100 employs the top emission method, the second electrode 140 is preferably made of a material with high light transmittance. Thus, the efficiency for taking out the light emission of the luminous layer 133 can be improved. Examples of the material with high light transmittance are indium tin oxide (ITO), indium zinc oxide (IZO), fluorine-doped tin oxide (FTO) and tin oxide (SnO₂).

On the other hand, in the case where the organic EL device 100 employs the bottom emission method, the second electrode 140 is preferably made of a light reflecting material. In this case, the light emitted from the luminous layer 133 to the side of the second electrode 140 is reflected on the second electrode 140 with the light reflecting property toward the first electrode 120. Therefore, the efficiency for taking out the light emission of the luminous layer 133 can be improved. Examples of the light reflecting material are aluminum (Al) and platinum (Pt).

The second electrode 140 may have a layered structure including a layer made of a material with a small work function such as calcium (Ca) and a layer made of a material stable against oxygen and having high conductivity such as aluminum (Al) (i.e., a layered structure of a Ca/Al layer, a Ce/Al layer, a Cs/Al layer, a Ba/Al layer or the like). Alternatively, the second electrode 140 may be a layer made of an alloy of a material with a small work function and a material stable against oxygen and having high conductivity (i.e., an alloy such as a Ca:Al alloy, a Mg:Ag alloy, a Li:Al alloy or the like). A material with a small work function such as calcium (Ca) is comparatively easily oxidized. However, when this structure is employed, the material with a small work function that is comparatively easily oxidized is covered with the material stable against oxygen. Therefore, the oxidation of the material with a small work function can be effectively suppressed. Accordingly, the organic EL device 100 can attain a long life.

The second electrode 140 may have a layered structure including a thin insulating layer and a layer with a small work function (i.e., a layered structure of a LiF/Al layer, a LiF/Ca/Al layer, a BaF₂/Ba/Al layer or the like). Alternatively, the second electrode 140 may be a layer obtained by doping a transparent conductive material with a material having a small work function (i.e., an ITO:Cs layer, an IDIXO:Cs layer, a SnO₂:Cs layer or the like). Alternatively, the second electrode 140 may have a layered structure including a layer of a transparent conductive material and a layer of a material with a small work function (i.e., a layered structure of a Ba/ITO layer, a Ca/IDIXO layer, a Ba/SnO₂ layer or the like).

The luminous layer 133 includes one kind of or two or more kinds of luminescent materials. The luminescent materials are roughly divided into low-molecular weight luminescent materials, polymeric luminescent materials and precursors of the polymeric luminescent materials.

Examples of the low-molecular weight luminescent materials are an aromatic dimethyliden compound, an oxadiazole compound, a triazole derivative, a styrylbenzene compound, thiopyrazinedioxide derivative, a benzoquinone derivative, a naphthoquinone derivative, an anthraquinone derivative, a diphenoquinone derivative and a fluorenone derivative. Specifically, an example of the aromatic dimethyliden compound is 4,4′-bis(2,2′-diphenylvinyl)-biphenyl (DPVBi). An example of the oxadiazole compound is 5-methyl-2-[2-[4-(5-methyl-2-benzoxazolyl)phenyl]vinyl]benzoxazole. An example of the triazole derivative is 3-(4-biphenylyl)-4-phenyl-5-t-bitylphenyl-1,2,4-triazole (TAZ). An example of the styrylbenzene compound is 1,4-bis(2-methylstyryl)benzene. Also, examples of a low-molecular weight luminescent material including a metal are an azomethine zinc complex and a (8-hydroxyquinolinate) aluminum complex (Alq₃).

Examples of the polymeric luminescent materials are poly(2-decyloxy-1,4-phenylene) (DO-PPP), poly[2,5-bis-[2-(N,N,N-triethylammonium)ethoxy]-1,4-phenyl-o-1,4-phenylene]dibromide (PPP-Net³⁺), poly[2-(2′-ethylhexyloxy)-5-methoxy-1,4-phenylenevinylene] (MEH-PPV), poly[5-methoxy-(2-propanoxysulfonide)-1,4-phenylenevinylene] (MPS-PPV), poly[2,5-bis-(hexyloxy)-1,4-phenylene-(1-cyanovinylene)] (CN-PPV), poly(9,9-dioctylfluorene) (PDAF) and polyspiro (PS).

Examples of the precursors of the polymeric luminescent materials are a PPV precursor, a PNV precursor and a PPP precursor.

The luminous layer 133 may further include an emission assisting agent, a charge transport material, an additive such as a donor or an acceptor, a luminescent dopant, a leveling agent, a charge injection material, a binding resin or the like. Examples of the binding resin are polycarbonate and polyester.

The hole injection layer 131 improves the efficiency for injecting holes from the first electrode 120 to the luminous layer 133. When the hole injection layer 131 is provided, high efficiency for injecting holes into the luminous layer 133 and high luminous efficiency can be realized.

The hole injection layer 131 includes, one kind of or two or more kinds of hole injection materials. The hole injection materials are roughly divided into low-molecular weight materials and p-type conductive polymeric materials.

Examples of the low-molecular weight hole injection materials are metal phthalocyanines such as copper phthalocyanine (CuPc), phthalocyanines, 4,4′,4′-tris(3-methylphenylamino)triphenylamine (m-MTDATA) and N,N′-(3-methylphenyl)-1,1′-biphenyl-4,4′-diamine (TPD).

Examples of the p-type conductive polymeric materials are polyaniline (PANI), 3,4-polyethylenedioxythiophene/polystyrenesulfonate (PEDOT/PSS), polypyrrole, polyparaphenylenevinylene (PPV), polysilane, polysiloxane and their derivatives.

The hole injection layer 131 may further include, for example, an additive such as a donor or an acceptor, a leveling agent, a binding resin or the like.

The energy level of the highest occupied molecular orbital (hereinafter sometimes referred to as “HOMO”) of the hole injection layer 131 is preferably between the energy level of the first electrode 120 and the energy level of the HOMO of the hole transport layer 132. Thus, higher hole injecting efficiency can be realized.

The electron injection layer 135 improves the efficiency for injecting electrons from the second electrode 140 to the luminous layer 133. The electron injection layer 135 includes one kind of or two or more kinds of electron injection materials. The electron injection materials are divided into low-molecular weight materials and n-type conductive polymers.

Examples of the low-molecular weight electron injection materials are an azole derivative and an oxadiazole derivative. A specific example of the azole derivative is 3-(4-biphenyl)-4-phenyl-5-(4-t-butylphenyl) 1,2,4-triazole. A specific example of the oxadiazole derivative is 1,3-bis{[4-(4-diphenylamino)]phenyl-1,3,4-oxadiazole-2-il}benzene. An example of the n-type conductive polymers is polythiophene with high electron affinity.

The electron injection layer 135 may further include an additive such as a donor or an acceptor, a leveling agent, a binding resin or the like.

The energy level of the lowest unoccupied molecular orbital (hereinafter sometimes referred to as “LUMO”) of the electron injection layer 135 is preferably lower than the energy level of the second electrode 140 and higher than the LUMO level of the luminous layer 133. Thus, higher electron injecting efficiency can be realized.

In the organic EL device 100 of Embodiment 1, the hole transport layer 132 is made of a charge transport material including a polymeric compound having, in its polymer main chain, a condensed ring structure composed of plurality of rings including a pyrrole ring with the main chain being a conjugated system (hereinafter referred to as the “polymeric compound A”).

The polymeric compound A includes, in its polymer main chain, a condensed ring structure composed of a plurality of rings at least including a pyrrole ring. The polymeric compound A may include another structure in the polymer main chain.

The polymeric compound A preferably has a molecular weight not less than 1,000 and not more than 10,000,000. When the molecular weight is lower than 1,000, its film forming property is so low that it tends to be difficult to obtain a flat film. When the molecular weight is 1,000 or more, the film forming property can be improved. Therefore, the flatness of the hole transport layer 132 can be improved.

In the case where the molecular weight is higher than 10,000,000, its solubility in a solvent is so low that it tends to be difficult to form a homogenous hole transport layer 132. When the molecular weight is 10,000,000 or less, the solubility in a solvent can be improved. Therefore, the hole transport layer 132 can be easily formed.

The energy level of the HOMO of the polymeric compound A is higher than that of a luminescent material (such as a polyfluorene derivative) generally used for the luminous layer 133. Therefore, when the polymeric compound A is used, the efficiency for injecting holes into the luminous layer 133 can be improved. Accordingly, high luminous efficiency, high brightness, a long life and a low driving voltage can be realized.

The polymeric compound A has a large energy gap between the LUMO level and the HOMO level. Also, the LUMO level is higher than that of a luminescent material generally used for the luminous layer 133 as described above. In other words, the absolute value of the electron affinity of the hole transport layer 132 made of a hole transport material including the polymeric compound A is smaller than the absolute value of the electron affinity of the luminous layer 133. Therefore, the movement of electrons from the luminous layer 133 to the hole transport layer 132 can be effectively suppressed (which is designated as an electron blocking function). Accordingly, high luminous efficiency, high brightness, a long life and a low driving voltage can be realized.

Specifically, the polymeric compound A may be a polymeric compound having, in its polymer main chain, carbazole or carbazole derivative represented by Chemical Formula 1 below with the main chain being a conjugated system (hereinafter sometimes referred to as the “polymeric compound B”). 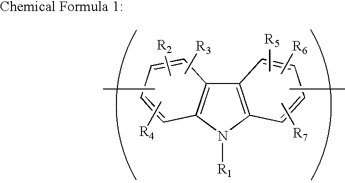
wherein each of R₁ through R₇ is a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

The hole transport layer 132 formed by using the polymeric compound B has a suitable energy band. Specifically, its HOMO level is higher than that of the luminous layer 133. Its LUMO level is higher than that of the luminous layer 133. Therefore, the movement of holes to the luminous layer 133 is eased while the movement of electrons from the luminous layer is suppressed. Accordingly, high luminous efficiency, high brightness and a low driving voltage can be realized.

The polymeric compound B has high thermal stability. Therefore, when the polymeric compound B is used, the hole transport layer 132 can attain high thermal stability.

The carbazole or carbazole derivative represented by Chemical Formula 1 included in the main chain of the polymeric compound B preferably polymerically bonded at the 3,6 position or the 2,7 position. The polymeric compound B in which the carbazole or the carbazole derivative is polymerically bonded at the 3,6 position or the 2,7 position can be easily synthesized. Therefore, it is inexpensively available, and hence, the hole transport layer can be inexpensively formed.

The substituent groups R₁ through R₇ are not particularly specified as far as the combination of them can attain the HOMO level of the polymeric compound B higher than that of the luminous layer 133 and the LUMO level of the polymeric compound B higher than that of the luminous layer 133. For example, each of R₁ through R₇ may be a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

From the viewpoint of the film forming property of the hole transport layer 132, R₁ is preferably an alkyl group with a carbon number of 2 or more or an arylalkyl group with a carbon number of 6 or more. In the case where the hole transport layer 132 is formed by the ink jet method, it is necessary to dissolve the polymeric compound B in a solvent with a comparatively high boiling point (of, for example, 150° C. or more). This is because if the polymeric compound B is dissolved in a solvent with a low boiling point, the solvent is vaporized during the formation of the hole transport layer 132 and hence it is difficult to form the hole transport layer 132 homogenously. When R₁ is an alkyl group with a carbon number of 2 or more or an arylalkyl group with a carbon number of 6 or more, the solubility in a solvent including an aromatic ring with a comparatively high boiling point can be improved. Accordingly, thus, the hole transport layer 132 can be formed to attain high homogeneity by the ink jet method. It is noted that examples of the solvent including an aromatic ring with a comparatively high boiling point are toluene, tetramethylbenzene and tetraethylbenzene.

Specific examples of the carbazole or carbazole derivative represented by Chemical Formula 1 are carbazoles or carbazole derivatives represented by Chemical Formulas 3 through 9 below.

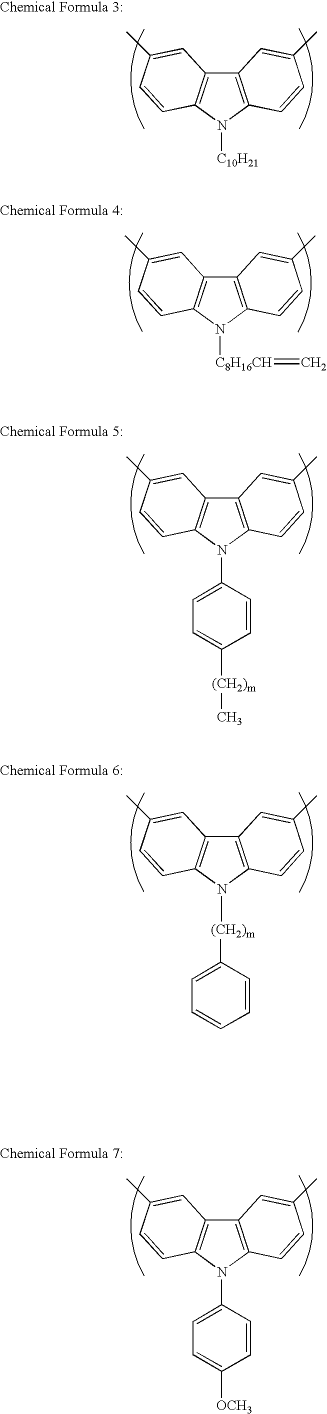

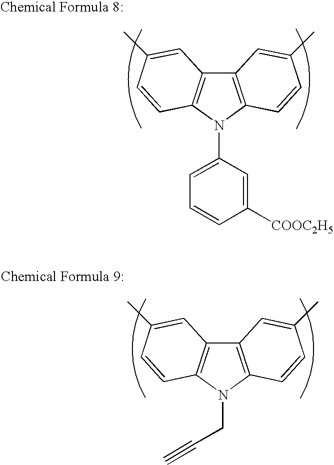

The polymeric compound B may be, for example, a homopolymer represented by any of Chemical Formulas 10 through 16 below. In the case where the polymeric compound B is a homopolymer, it is advantageously easily synthesized. It is noted that N-n-decyl polycarbazole represented by Chemical Formula 10 below is obtained by polymerizing a monomer represented by Chemical Formula 3. Also, N-n-9-decene-polycarbazole represented by Chemical Formula 11 below is obtained by polymerizing a monomer represented by Chemical Formula 4. N-4-alkylphenyl polycarbazole represented by Chemical Formula 12 below is obtained by polymerizing a monomer represented by Chemical Formula 5. N-4-phenylalkyl polycarbazole represented by Chemical Formula 13 below is obtained by polymerizing a monomer represented by Chemical Formula 6. N-4-methoxyphenyl polycarbazole represented by Chemical Formula 14 below is obtained by polymerizing a monomer represented by Chemical Formula 7. N-3-ethoxycarbonylphenyl polycarbazole represented by Chemical Formula 15 below is obtained by polymerizing a monomer represented by Chemical Formula 8. N-2-propynyl polycarbazole represented by Chemical Formula 16 below is obtained by polymerizing a monomer represented by Chemical Formula 9.

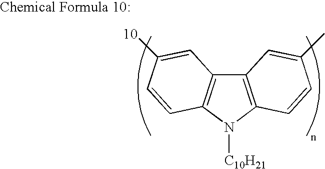

wherein n is a natural number of 5 or more.

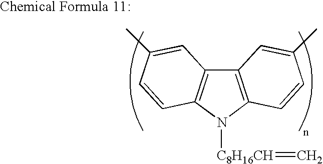

wherein n is a natural number of 5 or more.

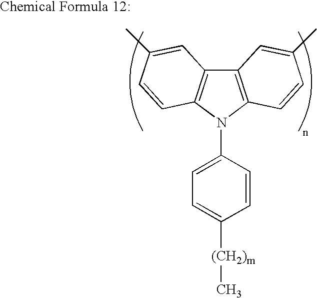

wherein n is a natural number of 5 or more and m is an integer of 0 through 12.

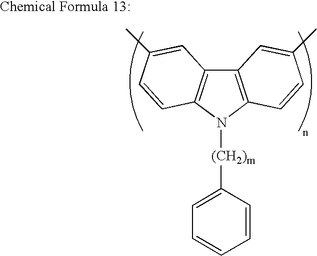

wherein n is a natural number of 5 or more and m is an integer of 0 through 4.

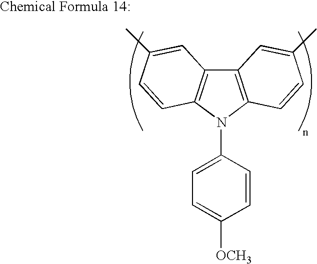

wherein n is a natural number of 5 or more.

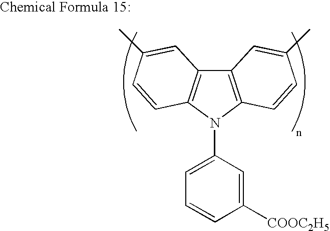

wherein n is a natural number of 5 or more.

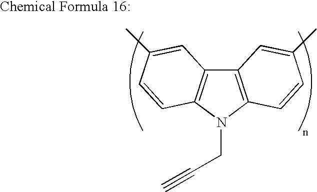

wherein n is a natural number of 5 or more.

The polymeric compound B may be a copolymer obtained by polymerizing a plurality of monomers represented by Chemical Formula 1 in which R₁ through R₇ are respectively different. For example, the polymeric compound B may be a binary copolymer represented by any of Chemical Formulas 17 through 20 below. When it is a binary copolymer, material characteristics such as the ionization potential and the hole transport capability can be adjusted by changing the copolymer ratio. It is noted that the binary copolymer represented by Chemical Formula 17 is obtained by polymerizing a monomer represented by Chemical Formula 3 and a monomer represented by Chemical Formula 4. The binary copolymer represented by Chemical Formula 18 is obtained by polymerizing a monomer represented by Chemical Formula 3 and a monomer represented by Chemical Formula 9. The binary copolymer represented by Chemical Formula 19 is obtained by polymerizing a monomer represented by Chemical Formula 5 and a monomer represented by Chemical Formula 3. The binary copolymer represented by Chemical Formula 20 is obtained by polymerizing a monomer represented by Chemical Formula 7 and a monomer represented by Chemical Formula 3.

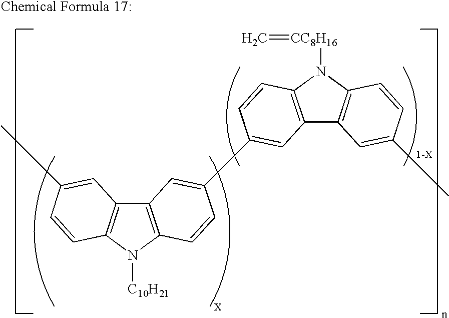

wherein n is a natural number of 5 or more and X is 0.0001 through 0.9999.

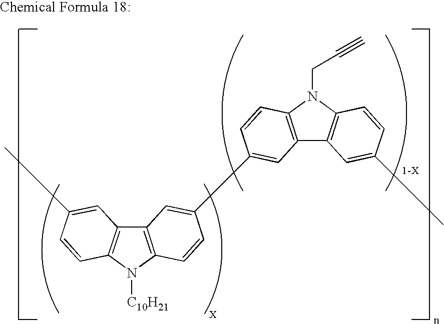

wherein n is a natural number of 5 or more and X is 0.0001 through 0.9999.

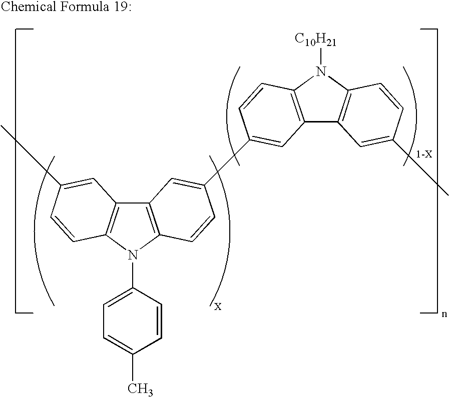

wherein n is a natural number of 5 or more and X is 0.0001 through 0.9999.

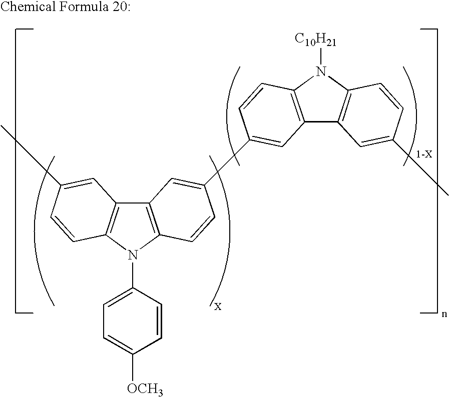

wherein n is a natural number of 5 or more and X is 0.0001 through 0.9999.

The polymeric compound B may be a copolymer of a monomer represented by Chemical Formula 1 and a monomer having another structure. In this case, the polymeric compound B can include a monomer having another function. Therefore, a function other than the hole transporting function can be provided to the polymeric compound B.

The polymeric compound B may be a copolymer of polyfluorene and a carbazole compound. In this case, the material characteristics such as the ionization potential and the hole transport capability can be adjusted by changing the copolymer ratio. Specifically, the polymeric compound B may be a copolymer represented by any of Chemical Formulas 21 through 24. The binary copolymer represented by Chemical Formula 21 is obtained by copolymerizing a carbazole compound represented by Chemical Formula 3 and dinormal hexyl polyfluorene. The binary copolymer represented by Chemical Formula 22 is obtained by copolymerizing a carbazole compound represented by Chemical Formula 7 and dinormal hexyl polyfluorene. The binary copolymer represented by Chemical Formula 23 is obtained by copolymerizing a carbazole compound represented by Chemical Formula 8 and dinormal hexyl polyfluorene. The ternary copolymer represented by Chemical Formula 24 is obtained by copolymerizing a carbazole compound represented by Chemical Formula 3, a carbazole compound represented by Chemical Formula 4 and dinormal hexyl polyfluorene.

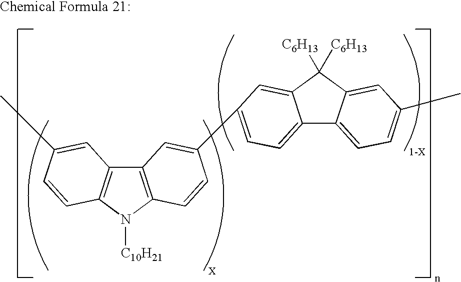

wherein n is a natural number of 5 or more and X is 0.0001 through 0.9999.

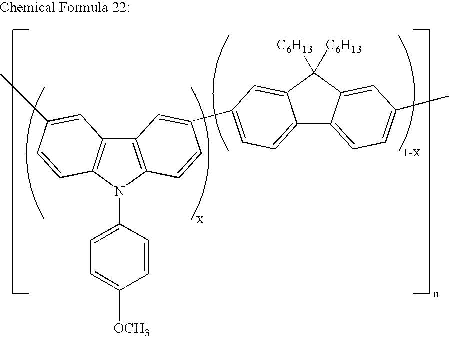

wherein n is a natural number of 5 or more and X is 0.0001 through 0.9999.

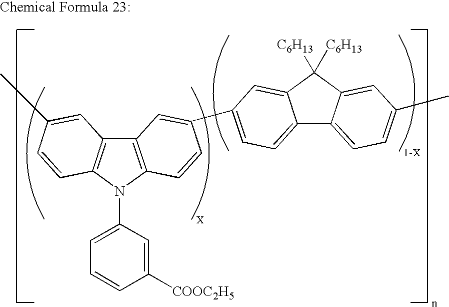

wherein n is a natural number of 5 or more and X is 0.0001 through 0.9999.

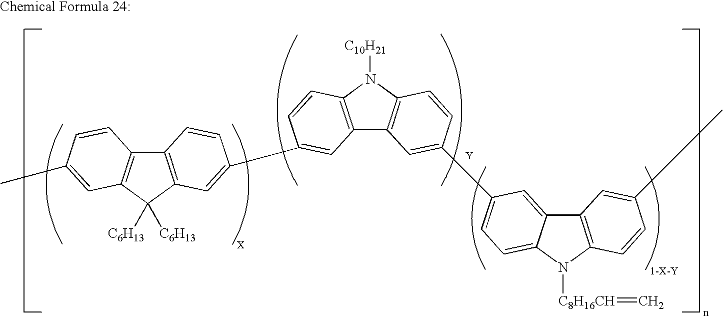

wherein n is a natural number of 5 or more, X is 0.0001 through 0.9998 and Y is 0.0001 through 0.9998.

Alternatively, the polymeric compound B may be a copolymer of a silane compound and a carbazole compound. Specifically, it may be a copolymer represented by any of Chemical Formulas 25 and 26 below. In this case, the material characteristics such as the ionization potential and the hole transport capability can be adjusted by changing the copolymer ratio. The binary copolymer represented by Chemical Formula 25 is obtained by copolymerizing a carbazole compound represented by Chemical Formula 3 and methylphenyl silane. The binary copolymer represented by Chemical Formula 26 is obtained by copolymerizing a carbazole compound represented by Chemical Formula 3 and phenetylphenyl silane.

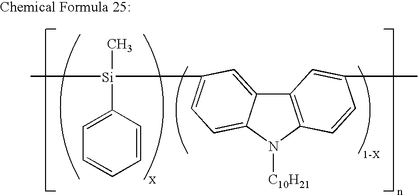

wherein n is a natural number of 5 or more and X is 0.0001 through 0.9999.

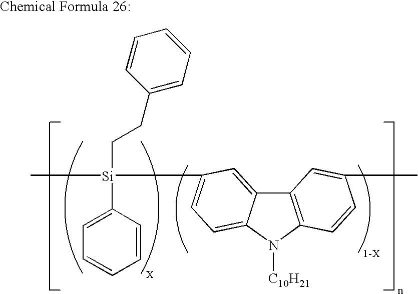

wherein n is a natural number of 5 or more and X is 0.0001 through 0.9999.

Alternatively, the polymeric compound B may be a copolymer of a triphenylamine compound and a carbazole compound. Specifically, it may be a polymer represented by any of Chemical Formulas 27 through 30 below. In this case, the material characteristics such as the ionization potential and the hole transport capability can be adjusted by changing the copolymer ratio. The binary copolymer represented by Chemical Formula 27 is obtained by copolymerizing a carbazole compound represented by Chemical Formula 3 and (3-ethoxycarbonylphenyl)diphenylamine. The binary copolymer represented by Chemical Formula 28 is obtained by copolymerizing a carbazole compound represented by Chemical Formula 3 and (4-methoxyphenyl)diphenylamine. The binary copolymer represented by Chemical Formula 29 is obtained by copolymerizing a carbazole compound represented by Chemical Formula 3 and N,N′-di(ethoxycarbonylphenyl)-N—N′-diphenylbenzidine. The binary copolymer represented by Chemical Formula 30 is obtained by copolymerizing a carbazole compound represented by Chemical Formula 3 and (3-ethoxycarbophenyl)diphenylamine.

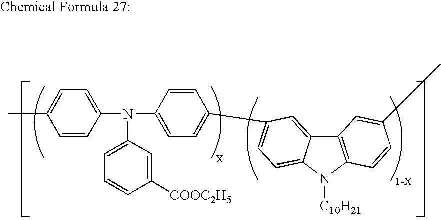

wherein n is a natural number of 5 or more and X is 0.0001 through 0.9999.

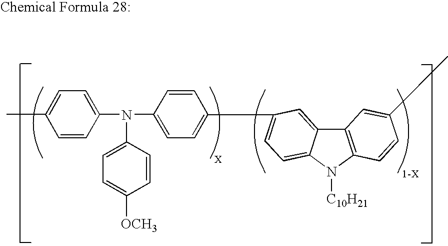

wherein n is a natural number of 5 or more and X is 0.0001 through 0.9999.

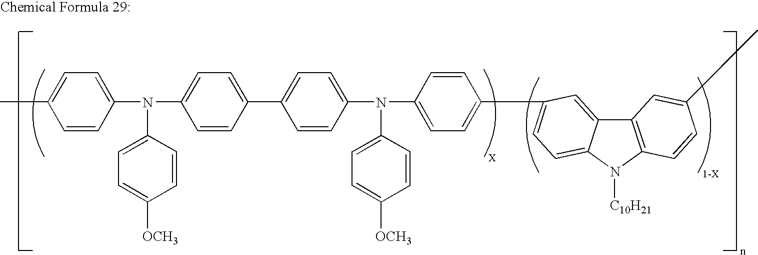

wherein n is a natural number of 5 or more and X is 0.0001 through 0.9999.

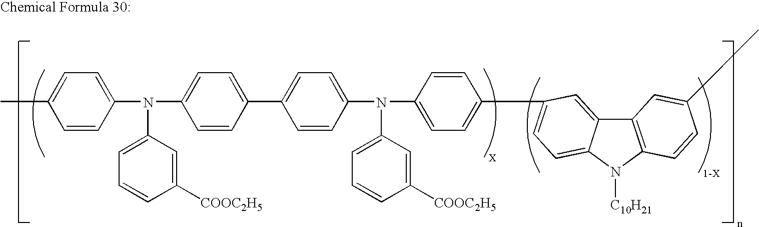

wherein n is a natural number of 5 or more and X is 0.0001 through 0.9999.

Furthermore, the hole transport layer 132 may be made of one kind of or two or more kinds of hole transport materials described above (such as the polymeric compound A and the polymeric compound B).

Also, the hole transport layer 132 may further include an additive such as a donor or an acceptor, a leveling agent, a binding resin, another high polymer, another hole transport material or the like.

Specifically, the hole transport layer 132 may further include a polymeric compound such as poly(N-vinylcarbazole), polyaniline, polythiophene, poly(p-phenylenevinylene), poly(2,5-phenylenevinylene), their derivatives, polycarbonate, polysiloxane, polymethyl acrylate, polymethyl methacrylate, polystyrene, polyvinyl chloride or poly(ethersulfone). Also, it may further include 4-4′-bis(N-3-methylphenyl-N-phenylamino)biphenyl, 1,3,5-tris(N,N-diphenylamino)benzene or any of their derivatives. It may further include an azole derivative, an oxadiazole derivative or the like as an electron transport material. An example of the azole derivative is 3-4(biphenyl)-4-phenyl-5-(4-t-butylphenyl)1,2,4-triazole. An example of the oxadiazole derivative is 1,3-bis{[4-(4-diphenylamino)]phenyl-1,3,4-oxadiazole-2-il}benzene.

The electron transport layer 134 improves the efficiency for transporting electrons injected from the second electrode 140 to the luminous layer 133. The electron transport layer 134 may include, for example, the polymeric compound B. When it includes the polymeric compound B, the electron injecting efficiency and the electron transporting efficiency can be improved.

In order to realize high electron transporting performance and high brightness, the electron transport layer 134 preferably includes a copolymer of a monomer of the carbazole or carbazole derivative represented by the aforementioned Chemical Formula 1 and a monomer with high electron transporting performance. Specifically, the electron transport layer 134 preferably includes one kind of or two or more kinds of copolymers represented by any of the aforementioned Chemical Formulas 21 through 24.

The electron transport layer 134 may further include an additive such as a donor or an acceptor, a leveling agent, a binding resin or the like.

The thickness of each of the hole injection layer 131, the hole transport layer 132, the luminous layer 133, the electron transport layer 134 and the electron injection layer 135 is preferably not less than 0.5 nm and not more than 1 μm and more preferably not less than 10 nm and not more than 200 nm.

When the thickness of each layer is smaller than 0.5 nm, probability of the occurrence of pin holes tends to be increased. When the thickness of each layer is 0.5 nm or more, the occurrence of pin holes can be effectively suppressed. Also, in order to more effectively suppress the occurrence of pin holes, the thickness of each layer is preferably 10 nm or more.

When the thickness of each layer is larger than 1 μm, the electric resistance is increased so that the driving voltage of the organic EL device 100 tends to be increased. When the thickness of each layer is 1 μm or less, the driving voltage can be effectively lowered. In order to realize a lower driving voltage, the thickness of each layer is preferably 200 nm or less.

The sealing cap 150 shuts off the first electrode 120, the organic layer 130 and the second electrode 140 from the air. When the sealing cap 150 is provided, degradation of the organic EL device 100 caused by invasion of oxygen and water into the device can be effectively suppressed.

The sealing cap 150 preferably has low oxygen permeability. For example, the sealing cap 150 can be made of glass or a metal.

In order to more effectively prevent the invasion of oxygen and water into the device, the sealing cap 150 is preferably filled with an inert gas such as nitrogen or argon. In order to further more effectively prevent the invasion of oxygen and water into the device, the sealing cap 150 is preferably provided with a moisture absorbing agent such as barium oxide.

Next, a method for fabricating the organic EL device 100 will be described.

First, a conductive film of indium tin oxide (ITO) or the like is formed on a substrate 110 of glass or the like. The formation may be performed by dry process or wet process. Specifically, sputtering, vapor deposition, an EB method, an MBE method or the like is employed as the dry process. Alternatively, a spin coating method, a printing method, an ink jet method or the like is employed as the wet process.

The formed conductive film is patterned into a desired shape by a patterning method such as photolithography, so as to form a first electrode 120.

A hole injection layer 131 is formed on the substrate 110 by applying a hole injection material such as polyparaphenylenevinylene (PPV) by mask evaporation, a transferring method, the spin coating method, a casting method, a dipping method, a bar coating method, a roll coating method, the ink jet method or the like.

Among the aforementioned methods, the ink jet method is particularly preferably employed for forming the hole injection layer 131. When the ink jet method is employed, the hole transport layer 131 can be inexpensively and easily formed. Also, fine patterning can be easily performed. An ink used in the ink jet method can be prepared by dissolving the hole injection material such as PPV in a solvent such as pure water, methanol, ethanol, THF, chloroform, xylene or trimethylbenzene. From the viewpoint of coating uniformity, the solvent used in the ink jet method preferably has a boiling point of 110° C. or more.

A hole transport layer 132 is formed on the hole injection layer 131 by applying a hole transport material such as N-n-decyl polycarbazole represented by Chemical Formula 10. A method for forming the hole transport layer is the mask evaporation, the transferring method, the spin coating method, the casting method, the dipping method, the bar coating method, the roll coating method, the ink jet method or the like.

Among these methods, the ink jet method is particularly preferably employed for forming the hole transport layer. When the ink jet method is employed, the hole transport layer 132 can be inexpensively and easily formed. Also, fine patterning can be easily performed. In the case where the hole transport layer 132 is formed by the ink jet method, a hole transport layer forming ink obtained by dissolving a hole transport material in a solvent with a boiling point of 110° C. or more is preferably used. When the boiling point of the solvent where the hole transport material is dissolved is low, the solvent is vigorously vaporized from the ink during the coating step. Therefore, it is difficult to form the hole transport layer 132 homogeneously. When the hole transport material is dissolved in a solvent with a boiling point of 110° C. or more, the vaporization of the solvent occurring in applying the ink by the ink jet method can be suppressed. Accordingly, the hole transport layer 132 can be formed homogeneously.

The solvent used in the hole transport layer forming ink preferably has an aromatic ring. This is because the hole transport material has high solubility in a solvent having an aromatic ring. When a solvent having an aromatic ring is used, a hole transport layer forming ink with a high coating property can be realized. Examples of the solvent having an aromatic ring and having a boiling point of 110° C. or more are toluene, xylene, trimethylbenzenes, tetralins, tetramethylbenzens and tetraethylbenzenes. Two or more of these solvents may be mixed to be used.

The hole transport material used in preparing the hole transport layer forming ink is preferably a polymeric compound that has, in a polymer main chain, carbazole or carbazole derivative represented by Chemical Formula 2 with the polymer main chain being a conjugated system. Since such a polymeric compound has high solubility in the solvent, the hole transport layer forming ink can attain a high coating property.

A luminous layer 133 is formed on the hole transport layer 132 by applying a luminescent material such as polyfluorene. A method for forming the luminous layer is the mask evaporation, the transferring method, the spin coating method, the casting method, the dipping method, the bar coating method, the roll coating method, the ink jet method or the like.

An electron transport layer 134 and an electron injection layer 135 are successively applied on the luminous layer 133. A method for forming these layers is the mask evaporation, the transferring method, the spin coating method, the casting method, the dipping method, the bar coating method, the roll coating method, the ink jet method or the like.

It is noted that the ink jet method is suitably used similarly in forming the luminous layer 133, the electron transport layer 134 and the electron injection layer 135. A solvent used for preparing an ink for forming these layers is preferably pure water, methanol, ethanol, THF, chloroform, xylene, trimethylbenzene or the like. In particular, a solvent with a boiling point of 110° C. or more is more preferred among these solvents.

A second electrode 140 is formed on the charge injection layer 135 by applying an electrode material such as indium tin oxide (ITO). The application method may be the dry process or the wet process. Specifically, the sputtering, the vapor deposition, the EB method, the MBE method or the like is employed as the dry process. Alternatively, the spin coating method, the printing method, the ink jet method or the like is employed as the wet process.

Ultimately, the organic EL device 100 is sealed by adhering a sealing cap 150 of glass or the like with a UV setting resin or the like. The step for adhering the sealing cap 150 is preferably performed in an inert gas such as nitrogen or argon. Thus, the invasion of oxygen or water between the sealing cap 150 and the organic EL device 100 can be suppressed.

Next, a method for fabricating the polymeric compound B suitably used as the hole transport material will be described.

The polymeric compound B can be synthesized by using a Yamamoto coupling reaction or the like.

The synthesis method will be described in detail by exemplifying N-alkyl-3,6-polycarbazole.

First, in an inert gas atmosphere such as nitrogen or argon, 3,6-dibromocarbazole and 1 through 1.1 equivalent of bromoalkane are dissolved in N,N-dimethylformamide (DMF). The resultant is allowed to stand for 24 hours at 50° C. with stirring. Thereafter, water is added to the resultant reaction solution cooled. Furthermore, dichloromethane is added thereto, so as to extract a product. The thus extracted product is purified by a purification method such as column chromatography, so as to give N-alkyl-3,6-dibromocarbazole.

The Yamamoto coupling reaction is caused by using the thus obtained N-alkyl-3,6-dibromocarbazole as a monomer. Specifically, with bis(1,5-cyclooctanediene)nickel (Ni(COD)₂), that is, zero-valent nickel, used as a catalyst, a polymerization reaction is caused between the N-alkyl-3,6-dibromocarbazole and an equivalent of 2,2′-bipyridyl (bpy) in the presence of 1,5-cyclooctanediene (COD) in an inert gas atmosphere at 60° C. Thereafter, the resultant reaction solution is poured into alcohol. The thus obtained solid matter is dried under reduced pressure (at room temperature for 24 hours). Furthermore, the resultant is dissolved again in an organic solvent such as THF, and an insoluble matter is removed with a filter having a pore size of 0.1-0.01 μm. Then, the resultant solution is precipitated again in alcohol, resulting in giving N-alkyl-3,6-polycarbazole.

Next, a method for synthesizing N-alkyl-2,7-polycarbazole will be described in detail.

First, N-alkyl-2,7-dibromocarbazole, that is, a monomer of N-alkyl-2,7-polycarbazole, is synthesized. Then, for example, the Yamamoto coupling reaction is caused with the thus obtained N-alkyl-2,7-dibromocarbazole used as a monomer, so that N-alkyl-2,7-polycarbazole can be polymerized.

Specifically, in the presence of triphenylphosphine, zinc, 2,2′-bipyridine and nickel chloride (NiCl₂), a polymerization reaction of N-alkyl-2,7-dibromocarbazole is caused in N—N-dimethylacetamide at 80° C. in an inert gas atmosphere. Next, the resultant reaction solution is poured into alcohol, and the thus obtained solid matter is dried under reduced pressure (at room temperature for 24 hours). Then, the resultant is dissolved again in an organic solvent such as THF, and an insoluble matter is removed with a filter having a pore size of 0.1-0.01 μm. Then, the resultant solution is precipitated again in alcohol, so as to give N-alkyl-2,7-polycarbazole.

In the case where the polymeric compound thus obtained is used as the charge transport layer, it is preferred that polymer purification such as reprecipitation purification or Soxhlet extraction is performed. This is because when the purity of the compound is low, the luminescent characteristic is low and the life is short.

### Embodiment 2

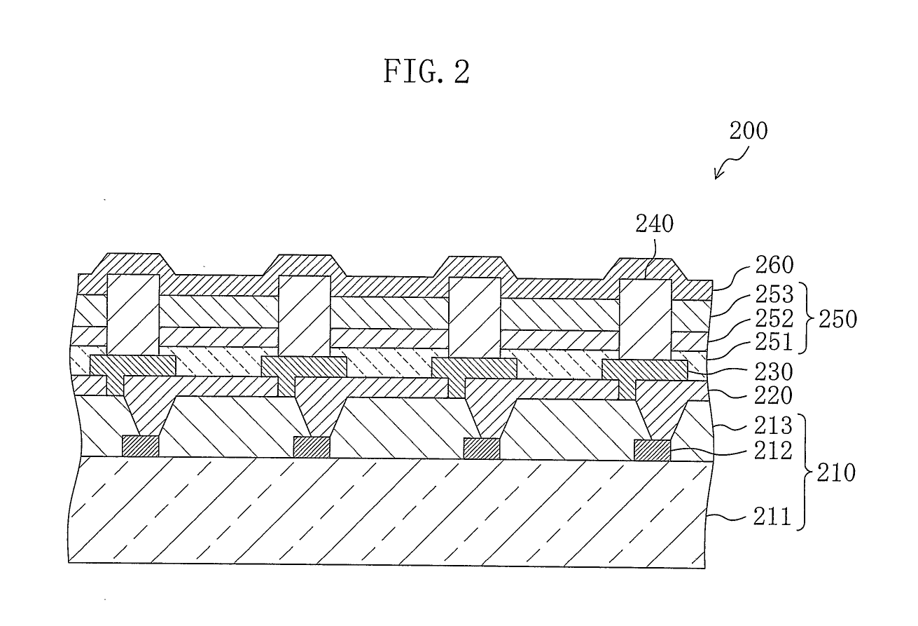

FIG. 2 is a schematic cross-sectional view of an organic EL image display apparatus 200 according to Embodiment 2.

The image display apparatus 200 includes a substrate 210, a plurality of first electrodes 220, a second insulating layer 230, a partition wall 240, a plurality of organic layers 250 and a second electrode 260.

The plural first electrodes 220 are arranged on the substrate 210 in the form of a matrix. The second insulating layer 230 insulates the adjacent plural first electrodes 220 from one another. The partition wall 240 is provided on the second insulating layer 230. Each of the plural organic layers 250 is provided on each first electrode 220. The plural organic layers 250 are separated from one another by the partition wall 240. The second electrode 260 is provided so as to cover the plural organic layers 250 and the partition wall 240.

The substrate 210 includes an insulating substrate 211, a plurality of TFTs 212 and a first insulating layer 213. The plural TFTs 212 are provided on the insulating substrate 211 in the form of a matrix.

The organic layer 250 includes a luminous layer 253 and a charge transport layer composed of a hole injection layer 251 and a hole transport layer 252.

In the image display apparatus 200 of Embodiment 2, the organic layer 250 includes the luminous layer 253, the hole injection layer 251 and the hole transport layer 252, which does not limit the invention. For example, the organic layer 250 may include the luminous layer 253 and one of the hole injection layer 251, the hole transport layer 252, an electron transport layer and an electron injection layer.

The first electrode 220 injects holes into the organic layer 250. The second electrode 260 injects electrons into the organic layer 250. The hole injection layer 251 improves the efficiency for injecting the holes into the luminous layer 253. The hole transport layer 252 improves the efficiency for transporting the holes having been injected from the first electrode 220 to the luminous layer 250.

The plural TFTs 212 are provided correspondingly to respective pixels. Each of the plural TFTs 212 controls voltage application to the corresponding first electrode 220 connected through a contact hole formed in the first insulating layer 213. Therefore, in the image display apparatus 200, a voltage can be applied selectively to a pixel to which a lighting signal is input from the corresponding TFT 212.

The insulating substrate 211, the first electrode 220, the luminous layer 253, the hole injection layer 251 and the second electrode 260 can be made of, for example, materials similar to those exemplified in Embodiment 1.

The TFT 212 may be an amorphous silicon TFT, a polysilicon TFT or the like.

The first insulating layer 213 makes flat the surface of the insulating substrate 211 on which the TFTs 212 are provided. Also, it insulates the adjacent TFTs 212 from one another. The first insulating layer 213 can be made of an acrylic resin or the like.

The second insulating layer 230 insulates the adjacent first electrodes 220 from one another. The second insulating layer 230 can be made of an insulating material such as SiO₂.

The partition wall 240 partitions the organic layer 250 into the respective pixels. The partition wall 240 can be made of a photosensitive resin material such as an acrylic resin and a polyimide resin.

The hole transport layer 252 can be made of a charge transport material including the polymeric compound A as in Embodiment 1.

The polymeric compound A has a HOMO level higher than that of a luminescent material generally used for the luminous layer 253 such as a polyfluorene derivative. Accordingly, when the polymeric compound A is used as the hole transport material, the efficiency for injecting holes into the luminous layer 253 can be improved. As a result, high luminous efficiency, high brightness, a long life and a low driving voltage can be realized.

The polymeric compound A has a large energy gap between the LUMO and the HOMO. For example, it has a higher LUMO level than the luminescent material generally used for the luminous layer 253 such as a polyfluorene derivative. Therefore, when the polymeric compound A is used as the hole transport material, the hole transport layer 252 can attain smaller electron affinity than the luminous layer 253. Accordingly, the movement of electrons from the luminous layer 253 to the hole transport layer 252 can be effectively suppressed (which function is designated as the electron blocking function). As a result, high luminous efficiency, high brightness, a long life and a low driving voltage can be realized.

Specifically, the polymeric compound A may be the polymeric compound B.

When the polymeric compound B is used as the hole transport material, the hole transport layer 252 having a suitable energy band can be formed. More specifically, the hole transport layer 252 having a HOMO level higher than that of the luminous layer 253 and a LUMO level lower than that of the luminous layer 253 can be formed. As a result, high luminous efficiency, high brightness, a long life and a low driving voltage can be realized.

Also, the polymeric compound B has high thermal stability. Therefore, when the polymeric compound B is used as the hole transport material, the organic EL image display apparatus 200 can attain higher thermal stability.

The carbazole or carbazole derivative represented by the aforementioned Chemical Formula 1 and included in the polymer main chain of the polymeric compound B is preferably polymerically bonded at the 3,6 position or 2,7 position. A synthesis method for the polymeric compound B in which the carbazole or carbazole derivative is polymerically bonded at the 3,6 position or 2,7 position has already been confirmed. Therefore, such a compound is comparatively easily and inexpensively available. Accordingly, the organic EL image display apparatus 200 can be easily and inexpensively fabricated.

The substituent groups R₁ through R₇ are not particularly specified as far as the combination of them can attain the HOMO level of the polymeric compound B higher than that of the luminous layer 253 and the LUMO level of the polymeric compound B higher than that of the luminous layer 253. For example, each of R₁ through R₇ may be a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

From the viewpoint of the film forming property of the hole transport layer 252, R₁ of Chemical Formula 1 is preferably an alkyl group with a carbon number of 2 or more or an arylalkyl group with a carbon number of 6 or more. In the case where the hole transport layer 252 is formed by the ink jet method, it is necessary to dissolve the polymeric compound B in a solvent with a comparatively high boiling point (of, for example, 110° C. or more). This is because if the polymeric compound B is dissolved in a solvent with a low boiling point, the hole transport layer 252 cannot be homogeneously formed but concentration irregularly is caused therein. Also, an ink used for forming the hole transport layer preferably includes a solvent having an aromatic ring. This is because the polymeric compound A has high solubility in a solvent having an aromatic ring.

Examples of the solvent including an aromatic ring and having a boiling point of 110° C. or more are toluene, tetramethylbenzenes, tetralins, tetramethylbenzens and tetraethylbenzenes.

Specific examples of the carbazole or carbazole derivative represented by Chemical Formula 1 are carbazoles or carbazole derivatives represented by Chemical Formulas 3 through 8 described above.

The polymeric compound B may be, for example, any of homopolymers represented by Chemical Formulas 9 through 13 described above, binary polymers represented by Chemical Formulas 14 and 15 described above and a tertiary polymer represented by Chemical Formula 16 described above.

The polymeric compound B may be a copolymer of a monomer represented by the aforementioned Chemical Formula 1 and another monomer having another structure. Specifically, the polymeric compound B may be, for example, any of binary copolymers represented by the aforementioned Chemical Formulas 17 through 19 and 21 through 26 and a tertiary copolymer represented by the aforementioned Chemical Formula 20.

The hole transport layer 252 may be made of one kind of or two or more kinds of the aforementioned hole transport materials.

The hole transport layer 252 may further include an additive such as a donor or an acceptor, a leveling agent, a binding resin, another high polymer, another hole transport material or the like.

The thickness of the hole transport layer 252 is preferably not less than 0.5 nm and not more than 1 μm and more preferably not less than 10 nm and not more than 200 nm.

When the thickness of the hole transport layer 252 is smaller than 0.5 nm, probability of the occurrence of pin holes in the hole transport layer 252 tends to be increased. When the thickness of the hole transport layer 252 is 0.5 nm or more, the occurrence of pin holes can be effectively suppressed. Also, in order to more effectively suppress the occurrence of pin holes, the thickness of the hole transport layer 252 is preferably 10 nm or more.

When the thickness of the hole transport layer 252 is larger than 1 μm, the electric resistance of the hole transport layer 252 is increased so that the driving voltage of the organic EL device 200 tends to be increased. When the thickness of the hole transport layer 252 is 1 μm or less, the driving voltage can be effectively lowered. In order to realize a lower driving voltage, the thickness of the hole transport layer 252 is preferably 200 nm or less.

### Example

Now, an organic EL device 300 of an example will be described in detail with reference to the accompanying drawing.

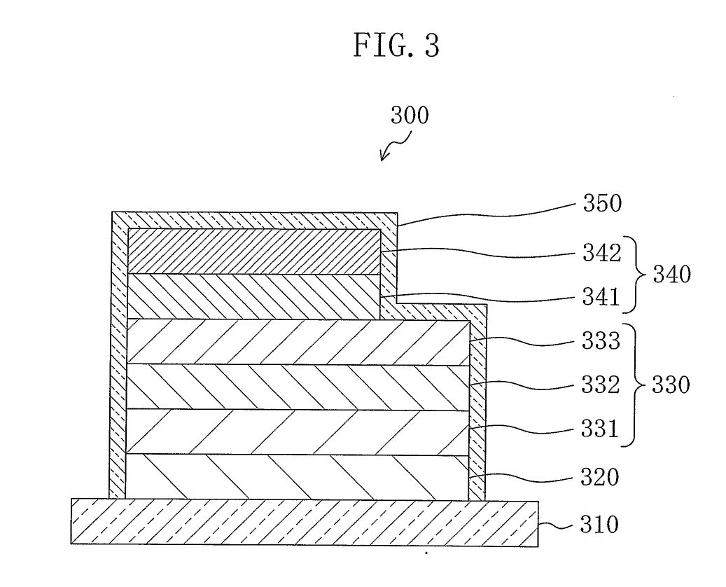

FIG. 3 is a cross-sectional view of the organic EL device 300 of this example.

First, N-n-decyl-3,6-polycarbazole to be used as the hole transport material was synthesized. Specifically, in a nitrogen atmosphere, 3,6-dibromocarbazole and 1 through 1.1 equivalent of bromodecane were dissolved in N,N-dimethylformamide (DMF). The resultant was allowed to stand in a nitrogen atmosphere for 24 hours at 50° C. with stirring. Thereafter, the resultant reaction solution was cooled. Then, water was added to the cooled reaction solution, and a product was extracted by using dichloromethane. The thus extracted product was purified by the column chromatography, so as to give a monomer, N-n-decyl-3,6-dibromocarbazole.

Next, the Yamamoto coupling reaction was caused by using the thus obtained N-n-decyl-3,6-dibromocarbazole as a monomer. Specifically, with bis(1,5-cyclooctanediene)nickel (Ni(COD)₂), that is, zero-valent nickel, used as a catalyst, a polymerization reaction was caused between the N-n-decyl-3,6-dibromocarbazole and an equivalent of 2,2′-bipyridyl (bpy) in the presence of 1,5-cyclooctanediene (COD) in an inert gas atmosphere at 60° C. Thereafter, the resultant reaction solution was poured into alcohol, and the thus obtained solid matter was dried under reduced pressure (at room temperature for 24 hours). Furthermore, the resultant was dissolved again in an organic solvent such as THF, and an insoluble matter was removed with a filter having a pore size of 0.1-0.01 μm. Then, the resultant solution was precipitated again in alcohol, resulting in giving N-n-decyl-3,6-polycarbazole.

The HOMO level, the LUMO level and the band gap of the thus obtained N-n-decyl-3,6-polycarbazole were measured and calculated as follows:

A measuring sample was fabricated by forming a thin film of N-n-decyl-3,6-polycarbazole with a thickness of 100 nm on a glass substrate (manufactured by Coning; 1737 glass substrate) by the spin coating. The absorption spectrum in a range of 250 nm through 450 nm of the measuring sample was measured with a spectrophotometer (manufactured by Nicolet; MAGNA-IR760SPECTROMETER). On the basis of the wavelength of the absorption edge of the thus measured absorption spectrum, the energy gap of the N-n-decyl-3,6-polycarbazole was calculated. The HOMO level (ionization potential) was measured by the atmospheric photoelectron spectroscopy by using AC-1 (manufactured by Riken Keiki Co., Ltd.) as a measuring apparatus. On the basis of the energy gap and the HOMO level thus obtained, the LUMO level of the N-n-decyl-3,6-polycarbazole was calculated.

The organic EL device 300 of this example was fabricated by using, as the hole transport material, the N-n-decyl-3,6-polycarbazole obtained in the aforementioned manner.

A glass substrate 310 (manufactured by Asahi Glass Co., Ltd.) on which a first electrode 320 of indium tin oxide (ITO) having a thickness of 15 nm in the shape of stripes with a width of 2 mm had been formed was prepared. A hole injection layer forming ink was prepared by dissolving PEDOT/PSS in water as a hole injection material. The hole injection layer forming ink was applied on the glass substrate 310 by the spin coating at 3000 rpm for 50 seconds, so as to form a hole injection layer 331 with a thickness of 50 nm.

A 1.0 wt % tetrahydrofuran solution of N-n-decyl-3,6-polycarbazole was applied on the hole injection layer 331 in a nitrogen atmosphere within a glove box at 2000 rpm for 50 seconds. The resultant film was baked at 150° C. for 1 hour, so as to form a hole transport layer 332 with a thickness of 50 nm.

A 1.2 wt % xylene solution of a blue luminescent material polyfluorene derivative was applied as a luminescent material on the hole transport layer 332 by the spin coating at 1500 rpm for 50 seconds. The resultant film was baked at 150° C. for 1 hour, so as to form a luminous layer 333 with a thickness of 80 nm.

A Ca layer 341 with a thickness of 20 nm was formed by vapor depositing Ca on the luminous layer 333 at a pressure of 10⁻⁵ Pa at a deposition rate of 0.1 nm/sec. An Al layer 342 with a thickness of 1000 nm was stacked on the Ca layer 341 by vapor depositing Al at a pressure of 10⁻⁵ Pa at a deposition rate of 20 nm/sec. Thus, a second electrode 340 was formed, resulting in obtaining the organic EL device 300.

Ultimately, a sealing cap 350 (commercially available; manufactured by Asahi Glass Co., Ltd.) with a size of 20 mm square and the peripheral portion of the organic EL device 300 were sealed with a UV setting resin. In this sealing step, a pixel portion was covered with an aluminum foil or the like so that the organic layer could be prevented from degrading by UV used for curing the resin.

With respect to the blue luminescent material polyfluorene derivative used in forming the luminous layer 333 of the organic EL device 300, the HOMO level, the LUMO level and the energy gap were measured and calculated in the same manner as in the above description.

### Comparative Example

An organic EL device having the same structure as the organic EL device 300 of the example except that poly(N-vinylcarbazole) (PVCz), that is, a known hole transport material, was used as a hole transport material in forming a hole transport layer was fabricated as a comparative example.

Also, the HOMO level, the LUMO level and the energy gap of the PVCz were measured and calculated in the same manner as in the example.

TABLE 1

| | Hole transport | Hole transport layer of | Luminous |
|---|---|---|---|
| | layer of Example | Comparative Example | layer |
| Hole transport | N-n-decyl | Polyvinyl carbazole | — |
| material | polycarbazole | | |
| HOMO (eV) | −5.3 | −5.7 | −5.6 |
| LUMO (eV) | −2.0 | −2.7 | −2.5 |
| Energy gap (eV) | 3.3 | 2.9 | 3.1 |

In Table 1, the HOMO levels, the LUMO levels the energy gaps of the N-n-decyl-3,6-polycarbazole of the example and the PVCz of the comparative example are listed.

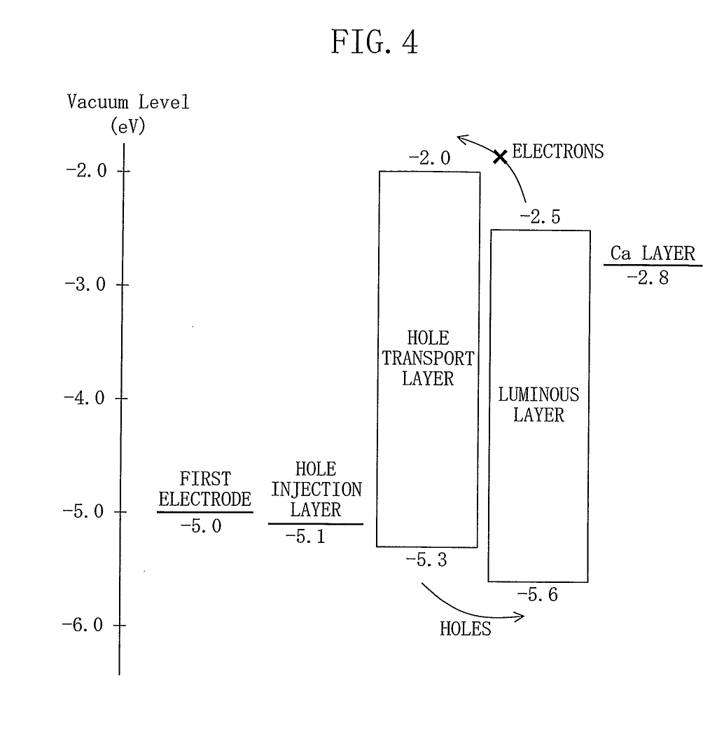

FIG. 4 is a schematic diagram of the energy level of the organic EL device of the example.

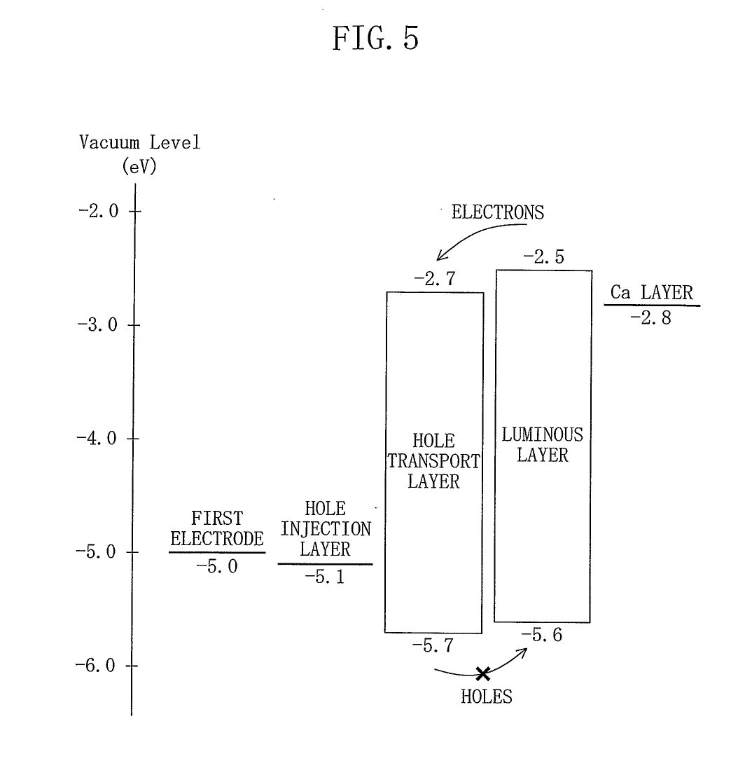

FIG. 5 is a schematic diagram of the energy level of the organic EL device of the comparative example.

As shown in Table 1 and FIGS. 4 and 5, the HOMO level of the hole transport layer of the organic EL device of the example is higher than the HOMO level of the luminous layer thereof. On the other hand, the HOMO level of the hole transport layer of the organic EL device of the comparative example is lower than the HOMO level of the luminous layer thereof. It is understood from this result that the efficiency for transporting holes from the hole transport layer to the luminous layer is low in the organic EL device of the comparative example. In contrast, it is understood that the efficiency for transporting holes from the hole transport layer to the luminous layer is high in the organic EL device of the example.

The LUMO level of the hole transport layer of the organic EL device of the example is higher than the LUMO level of the luminous layer thereof. In other words, the absolute value of the electron affinity of the hole transport layer is smaller than the absolute value of the electron affinity of the luminous layer in the organic EL device of the example. On the other hand, the LUMO level of the hole transport layer of the organic EL device of the comparative example is lower than the LUMO level of the luminous layer thereof. In other words, the absolute value of the electron affinity of the hole transport layer is larger than the absolute value of the electron affinity of the luminous layer in the organic EL device of the comparative example. Accordingly, electrons are easily moved from the luminous layer to the hole transport layer in the organic EL device of the comparative example. In contrast, the movement of electrons from the luminous layer to the hole transport layer is effectively suppressed in the organic EL device of the example, so that the electrons can be effectively confined in the luminous layer.

In this manner, the efficiency for transporting holes from the hole transport layer to the luminous layer is higher in the organic EL device of the example than in the organic EL device of the comparative example, and the movement of electrons from the luminous layer to the hole transport layer is effectively suppressed so that the electrons can be effectively confined in the luminous layer in the organic EL device of the example.

Embodiments 1 and 2 describe that the charge transport material of this invention can be used in an organic EL device and an organic EL image display apparatus. The application of the charge transport material of this invention is, however, not limited to them but it can be used in, for example, an organic solar cell, an organic semiconductor, a photoconductor and the like.

While the present invention has been described in preferred embodiments, it will be apparent to those skilled in the art that the disclosed invention may be modified in numerous ways and may assume many embodiments other than that specifically set out and described above. Accordingly, it is intended by the appended claims to cover all modifications of the invention that fall within the true spirit and scope of the invention.

1. An organic electroluminescence device comprising:
a substrate;
a first electrode provided on said substrate;
a luminous layer provided on said first electrode;
a second electrode provided on said luminous layer; and
a charge transport layer that is provided between said luminous layer and said first electrode or between said luminous layer and said second electrode and is made of a charge transport material including a polymeric compound having, in a polymer main chain, a condensed ring structure composed of a plurality of rings including a pyrrole ring with said polymer main chain being a conjugated system.

2. The organic electroluminescence device of claim 1,
wherein said polymeric compound has, in said polymer main chain, carbazole or carbazole derivative represented by the following Chemical Formula 1 with said polymer main chain being the conjugated system: 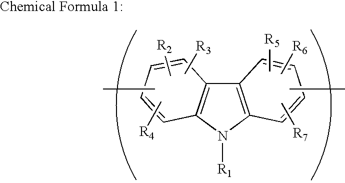
wherein each of R₁ through R₇ is a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

3. The organic electroluminescence device of claim 2,
wherein said carbazole or carbazole derivative represented by Chemical Formula 1 is polymerically bonded at the 3,6 position or 2,7 position.

4. The organic electroluminescence device of claim 1,
wherein said charge transport layer is a hole transport layer provided between said luminous layer and said first electrode.

5. The organic electroluminescence device of claim 4,
wherein said hole transport layer controls movement of electrons from said luminous layer to said hole transport layer.

6. The organic electroluminescence device of claim 4,
wherein an absolute value of electron affinity of said hole transport layer is smaller than an absolute value of electron affinity of said luminous layer.

7. The organic electroluminescence device of claim 1, further comprising a hole injection layer between said luminous layer and said first electrode.

8. A charge transport material comprising:
a polymeric compound having, in a polymer main chain, a condensed ring structure composed of a plurality of rings including a pyrrole ring with said polymer main chain being a conjugated system.

9. The charge transport material of claim 8,
wherein said polymeric compound has, in said polymer main chain, carbazole or carbazole derivative represented by the following Chemical Formula 1 with said polymer main chain being the conjugated system: 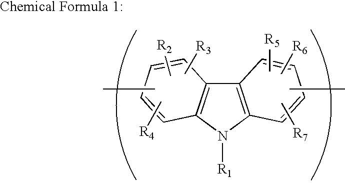
wherein each of R₁ through R₇ is a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

10. A charge transport layer forming ink comprising:
an organic solvent having a boiling point of 110° C. or more; and
a charge transport material dissolved in said organic solvent and including a polymeric compound having, in a polymer main chain, carbazole or carbazole derivative represented by the following Chemical Formula 2 with said polymer main chain being a conjugated system: 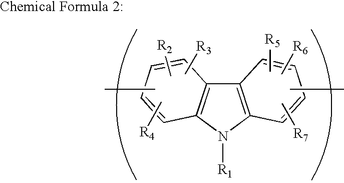
wherein R₁ is an alkyl group with a carbon number of 2 or more or an arylalkyl group with a carbon number of 6 or more, and each of R₂ through R₇ is a hydrogen atom, a halogen atom, an alkyl group, an aryl group, an arylalkyl group, an arylalkenyl group, an arylalkynyl group, an ether group, an ester group, an acyl group, an alkenyl group, an alkynyl group, an alkoxyl group, an alkylthio group, an arylamino group, an arylsilyl group, an arylalkoxyl group, an arylalkylthio group, an arylalkylamino group, an arylalkylsilyl group, an acyloxy group, an imino group or an amido group.

11. The charge transport layer forming ink of claim 10,
wherein said solvent is any of toluene, xylene, trimethylbenzenes, tetralins, tetramethylbenzens and tetraethylbenzenes.

12. An organic electroluminescence image display apparatus comprising an organic electroluminescence device, said organic electroluminescence device including:
a substrate;
a first electrode provided on said substrate;
a luminous layer provided on said first electrode;
a second electrode provided on said luminous layer; and
a charge transport layer that is provided between said luminous layer and said first electrode or between said luminous layer and said second electrode and is made of a charge transport material including a polymeric compound having, in a polymer main chain, a condensed ring structure composed of a plurality of rings including a pyrrole ring with said polymer main chain being a conjugated system.

13. An organic electroluminescence lighting apparatus comprising an organic electroluminescence device, said organic electroluminescence device including:
a substrate;
a first electrode provided on said substrate;
a luminous layer provided on said first electrode;
a second electrode provided on said luminous layer; and
a charge transport layer that is provided between said luminous layer and said first electrode or between said luminous layer and said second electrode and is made of a charge transport material including a polymeric compound having, in a polymer main chain, a condensed ring structure composed of a plurality of rings including a pyrrole ring with said polymer main chain being a conjugated system.
